(19) United States
(12) Patent Application Publication
(10) Pub. No.: US 2009/0165849 A1
(43) Pub. Date: Jul. 2, 2009

(54) TRANSPARENT SOLAR CELL MODULE

(75) Inventors: I-Min Chan, Taoyuan County (TW); Chao-Hsien Kuo, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/209,215

(22) Filed: Sep. 12, 2008

(30) Foreign Application Priority Data
Dec. 31, 2007 (TW) 96151505

(51) Int. Cl. H01L 31/00

(52) U.S. Cl. 136/256

(57) ABSTRACT

A transparent solar cell module including a transparent solar cell and an optical filter is provided. The transparent solar cell includes a transparent substrate and a transparent solar cell part located on a first surface of the transparen substrate. The optical filter is located on the transparent solar cell.

### CROSS-REFERENCE TO RELATED APPLICATION

This application claims the priority benefit of Taiwan application serial no. 96151505, filed on Dec. 31, 2007. The entirety of the above-mentioned patent application is hereby incorporated by reference herein and made a part of this specification.

### BACKGROUND OF THE INVENTION

1. Field of the Invention

The present invention generally relates to a transparent solar cell module.

2. Description of Related Art

Solar energy is a renewable and environment friendly energy that attracts the most attention for solving the problems of the shortage and pollution of petrochemical energies. Currently, solar cells become a considerably important research issue, as they can directly convert solar energy into electric energy.

The early solar cell is disposed on the roof. However, in cities with so many people and a limited area, the area of the top floor is limited with a small area for installation. The glass curtain wall of the vertical surface of the building has a large area and is not limited by government regulations, thus being a area available for the transparent solar cell module.

Building integrated photovoltaics (BIPVs) must have good light transmittance. Transparent solar cells have the advantages of energy saving and having beautiful appearance and also meet the requirements for humanity living in these applications.

Currently, relevant techniques about transparent thin film solar cells and methods for manufacturing the same have been disclosed in patents.

U.S. Pat. No. 4,795,500 sets forth a photovolatic device. The photovolatic device includes a first transparent substrate, a transparent conductive layer, a photoelectric conversion layer, a back electrode, and a photoresist. The photovolatic device has holes in the back electrode, the photoelectric conversion layer, and the transparent conductive layer for light transmission. The photoresist used in the photolithographic is not required to be removed for generating colorful effects, thus reducing the metallic luster of the back electrode.

U.S. Pat. No. 4,663,495 sets forth a transparent photovolatic module. Upper and lower electrodes of the transparent photovolatic module are made of transparent conductive oxide (TCO) to be irradiated on dual surfaces, and the unabsorbed light can be transmitted, thus forming the transparent photovolatic module.

U.S. Pat. No. 6,858,461 sets forth a partially transparent photovolatic module. In the photovolatic module, a portion of the metal electrode and the photoelectric conversion layer is removed by laser scribing to form at least one groove, such that the photovolatic module is partially transparent.

Other relevant patents, such as U.S. Pat. Nos. 4,623,601 and 6,180,871, also set forth other solar cells.

Although the current transparent amorphous silicon thin-film solar cells or the transparent dye-sensitized solar cells can obtain electric power, the silicon thin film or the dye absorbs the light in specific band, thus generating red or yellow color on the film. When being applied on glass curtain, the external wall of the building does not lose beautiful appearance, but the indoor color hue changes, thus resulting in failure to meet the requirements. Therefore, how apply the BIPV in glass curtain without changing the indoor color hue is an important issue in the future.

On the other hand, although see-through type products have a transmittance increased by 10%, but the efficiency is lost by 30%, and thus the cost of power generation per Walt is appropriately increased by about 30%. Further, in addition to chemical vapor deposition (CVD), a laser process is further required to be added for the transparent products, thus increasing the manufacturing cost and generating the problem of the glare, as a result, the see-through type products are not suitable for being watched at a close distance or for a long period of time by eyes.

### SUMMARY OF THE INVENTION

Accordingly, the present invention is directed to a transparent solar cell module capable of alleviating the sunlight spectrum distortion problem.

The present invention is directed to a transparent solar cell module capable of adjusting thechromaticity diagram of Commission International de l'Eclairage (CIE) the color rendering index, and the color temperature in the indoor.

The present invention is directed to a transparent solar cell module capable of being used as BIPV.

The present invention provides a transparent solar cell module including an optical filter and a transparent solar cell. The transparent solar cell includes a transparent substrate and a transparent solar cell part located on a first surface of the transparent substrate. The optical filter is located on the transparent solar cell.

In the transparent solar cell module according to an embodiment of the present invention, the optical filter is located on a second surface of the transparent substrate.

In the transparent solar cell module according to an embodiment of the present invention, the optical filter is located between the first surface of the transparent substrate and the transparent solar cell part.

In the transparent solar cell module according to an embodiment of the present invention, the transparent solar cell part is located between the optical filter and the transparent substrate.

The transparent solar cell of the present invention is capable of alleviating the sunlight spectrum distortion problem.

The transparent solar cell of the present invention is capable of adjusting thechromaticity diagram of Commission International de l'Eclairage (CIE), the color rendering index, and the color temperature in the indoor.

The transparent solar cell of the present invention is capable of being used as BIPV.

In order to make the objects and other objects, features and advantages of the present invention clearer and more understandable, the following embodiments are illustrated in detail with reference to the appended drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1 to 3 are schematic cross-sectional views of a transparent solar cell module according to embodiments of the present invention respectively.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

A solar cell in the transparent solar cell module of the present invention has an optical filter disposed therein, so as to alleviate the problem of indoor color hue changes due to a photoelectric conversion layer of the transparent solar cell module merely absorbing the light in specific band, thereby achieving the purpose of controlling the chromaticity diagram of Commission International de l'Eclairage (CIE) (CIE), the color rendering index (Ra), and the color temperature (CT) of the transmission spectrum of the transparent solar cell. Hereinafter, the position relationship of the optical filter in the transparent substrate is illustrated with reference to several embodiments, but the present invention is not limited thereto.

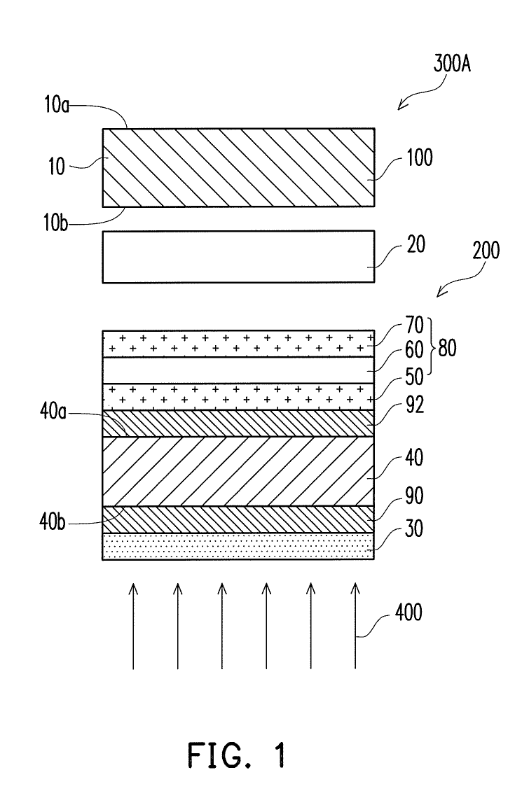

FIGS. 1 to 3 are schematic cross-sectional views of transparent solar cell modules according to embodiments of the present invention respectively.

Referring to FIGS. 1 to 3, the transparent solar cell module of the present invention includes a transparent substrate module 100, a transparent solar cell 200, and an optical filter 30. More specifically, the transparent substrate module 100 includes a transparent substrate 10. The transparent solar cell 200 includes a transparent substrate 40 and a transparent solar cell part 80. The transparent solar cell part 80 includes an electrode 50, a photoelectric conversion layer 60, and an electrode 70. The electrode 50 is disposed on the transparent substrate 40. The photoelectric conversion layer 60 is located between the electrode 50 and the electrode 70. The electrode 70 is in contact with an insulation layer 20, and thus the transparent solar cell 200 is packaged on a surface 10b of the transparent substrate 10 of the transparent substrate module 100. The optical filter 30 is located on the transparent solar cell 200. That is to say, the optical filter 30 can be located on the transparent substrate 40, between the transparent substrate 40 and the transparent solar cell part 80, or on the transparent solar cell part 80. The transparent substrate module 100, the transparent solar cell 200, and the insulation layer 20 in the figures are spaced by a certain distance for clarity. Hereinafter, the present invention is illustrated according to different positions of the optical filter 30 in the transparent solar cell 200.

### First Embodiment

Referring to FIG. 1, a transparent substrate 40 of a transparent solar cell 200 in a solar cell module 300A has an electrode 50, a photoelectric conversion layer 60, and an electrode 70 of a solar cell part 80 disposed on a surface 40a thereof. The transparent substrate 40 has an optical filter 30 disposed on a surface 40b thereof.

As the transparent substrate 40 has an optical filter 30 disposed on the surface 40b thereof, when sunlight 400 is incident on the second surface 40b of the transparent substrate 40, it passes through the optical filter 30, such that the light of a portion of band is filtered, and the light of another portion of band is absorbed at the transparent solar cell part 80 for generating energy power. The light of furtgher another portion of band passes through the transparent solar cell part 80 and the insulation layer 20, and finally passes through the transparent substrate module 100, such that the color hue of the light finally incident on a side of a surface 10a (indoor) of the transparent substrate 10 is adjusted into a specific range.

In an embodiment, in order to enhance the reflection of long-wavelength light for improving the efficiency of the elements, the transparent substrate 40 further has an anti-reflection layer 90 on the surface 40b thereof, and the anti-reflection layer 90 is located between the optical filter 30 and the transparent substrate 40. In another embodiment, the transparent substrate 40 further has an anti-reflection layer 92 on the surface 40a thereof, and the anti-reflection layer 92 is located between the transparent substrate 40 and the electrode 50 of the solar cell part 80. In another embodiment, the transparent substrate has the anti-reflection layer 90 and the anti-reflection layer 92 respectively on the surfaces 40b and 40a thereof.

### Second Embodiment

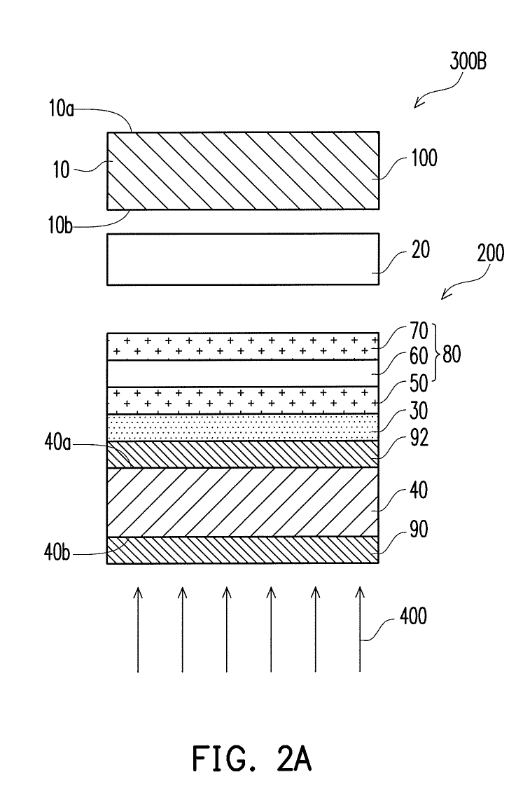

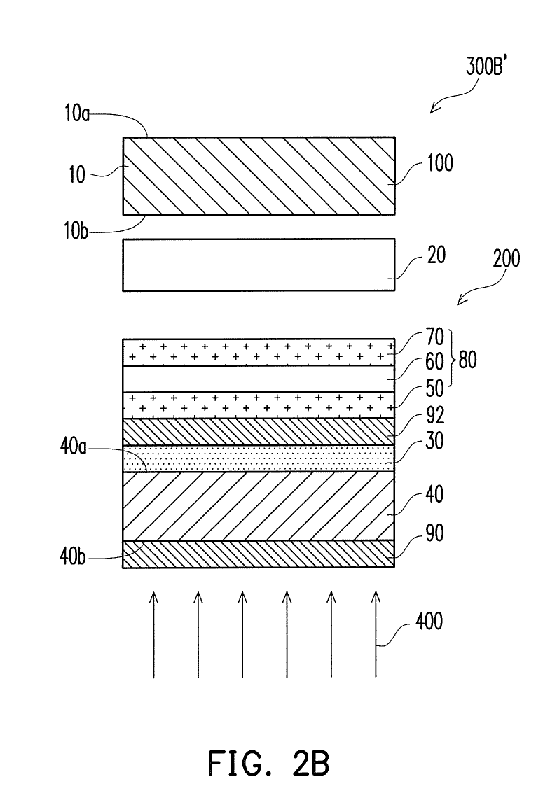

Referring to FIGS. 2A and 2B, transparent solar cell modules 300B and 300B′ have the same components as those in the first embodiment, but the position of the optical filter 30 is different from that in the transparent solar cell 200. In this embodiment, the optical filter 30 is located between the electrode 50 of the solar cell part 80 and the surface 40a of the transparent substrate 40. As the optical filter 30 is disposed between the transparent substrate 40 and the electrode 50, when sunlight 400 is incident on the surface 40b of the transparent substrate 40, it passes through the optical filter 30, the light of a portion of band is filtered, and the light of another portion of band is absorbed at the transparent solar cell part 80 for generating energy power. The light of further another portion of band passes through the transparent solar cell part 80 and the insulation layer 20, and finally passes through the transparent substrate module 100, such that the color hue of the light finally incident on a side of a surface 10a (indoor) of the transparent substrate 10 is adjusted into a specific range.

Similarly, in order to enhance the reflection of long-wavelength light and for improving the efficiency of the elements, the transparent substrate 40 further has an anti-reflection layer 90, 92 disposed on the two surfaces 40b and 40a thereof respectively, or has anti-reflection layers 90 and 92 disposed simultaneously. More particularly, the anti-reflection layer 90 is disposed on the surface 40b of the transparent substrate 40, the anti-reflection layer 92 is disposed on the surface 40a of the transparent substrate 40, such that the anti-reflection layer 92 is located between the optical filter 30 and the transparent substrate 40, as shown in FIG. 2A. Alternatively, the anti-reflection layer 90 is disposed on the surface 40b of the transparent substrate 40, the anti-reflection layer 92 is disposed between the optical filter 30 and the solar cell part 80, as shown in FIG. 2B.

### Third Embodiment

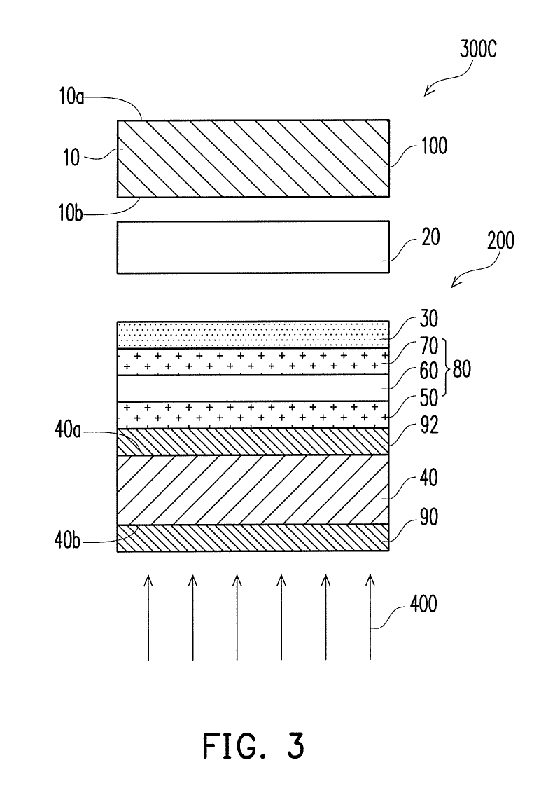

Referring to FIG. 3, a transparent solar cell module 300C has the same components as those in the first embodiment, but the position of the optical filter 30 is different from that in the transparent solar cell 200. In this embodiment, the optical filter 30 is located on a surface of the electrode 70 of the solar cell part 80 without the photoelectric conversion layer 60 disposed thereon, such that the optical filter 30 is located between the solar cell part 80 and the insulation layer 20.

As the electrode 70 of the solar cell part 80 has the optical filter 30 disposed thereon, when sunlight 400 is incident on the second surface 40b of the transparent substrate 40, the light of a portion of band is absorbed by the transparent solar cell part 80 for generating energy power, the light of the other portion of band passes through the transparent solar cell part 80 and the optical filter 30 with the light of a portion of band being filtered, and then passes through the insulation layer 20 and the transparent substrate module 100, such that the light finally incident on a side of a surface 10a (indoor) of the transparent substrate 10 is adjusted into a specific range.

Similarly, in order to enhance the reflection of long-wavelength light and for improving the efficiency of the elements, the transparent substrate 40 further has an anti-reflection layer 90, 92 disposed on the two surfaces 40b and 40a thereof respectively, or has the anti-reflection layers 90 and 92 disposed simultaneously. More particularly, the anti-reflection layer 90 can be disposed on the surface 40b of the transparent substrate 40, the anti-reflection layer 92 can be disposed on the surface 40a of the transparent substrate 40, such that the anti-reflection layer 92 is located between the transparent substrate 40 and the electrode 50 of the solar cell part 80.

The transparent solar cell 200 is a transparent dye-sensitized solar cell, a transparent silicon thin-film solar cell, a copper indium gallium diselenide (CIGS) solar cell module, a copper indium diselenide (CIS) solar cell module, or an transparent organic solar cell.

A material of the photoelectric conversion layer 60 is, for example, a dye, amorphous silicon, microcrystalline silicon, or an alloy thereof, such as SiGe, CdS, CuInGaSe (CIGS), CuInSe₂ (CIS), CdTe, organic materials, or a stacked multilayer structure thereof.

The shape and the structure of the electrode 50, the electrode 70, and the photoelectric conversion layer 60 of the transparent solar cell part 80 are not specially limited. The photoelectric conversion layer 60 can have a single junction or dual junctions, or multiple junctions.

The materials of the electrode 50 and the electrode 70 can be the same or different and can be, for example, transparent conductive oxide (TCO), such as indium tin oxide (ITO), fluorine doped tin oxide (FTO), aluminium doped zinc oxide (AZO), gallium doped zinc oxide (GZO), or a combination thereof.

The transparent substrate 40 can be a rigid substrate or a flexible substrate. The rigid substrate is, for example, a glass substrate serving as a curtain of a building. The flexible substrate is, for example, a plastic substrate.

The transparent substrate 10 can be a rigid substrate or a flexible substrate. The rigid substrate is, for example, a glass substrate serving as a curtain of a building. The flexible substrate is, for example, a plastic substrate. The transparent substrate 10 and the transparent substrate 40 can be the same or different.

A material of the insulation layer 20 is, for example, ethylene vinyl acetate (EVA), polyvinyl butyral (PVB), or another material with similar property.

The optical filter 30 limits the color standard (CIE) of the transmission spectrum of the transparent solar cell 200 within a rectangular region formed by CIE (0.10, 0.75) and CIE (0.25, 0.60), and adjusts the color rendering index (Ra) of the transmission spectrum of the transparent solar cell to be greater than 75, and adjusts the color temperature (CT) of the transmission spectrum of the transparent solar cell to 1000 to 10000 Kelvin degrees. The optical filter 30 is, for example, a stacked film formed by stacking a plurality of high-reflective index film layers having a reflective index n greater than 1.9 and a plurality of low-reflective index film layers having a reflective index n less than 1.9. The high-reflective index film layers are, for example, CeO₂, Cr₂O₃, Gd₂O₃, HfO₂, In₂O₃, ITO, La₂O₃, Nb₂O₅, Nd₂O₃, PbO, SnO₂, Ta₂O₅, TiO₂, V₂O₅, WO₃, ZrO₂, ZnO, ZnS, and ZnSe. The low-reflective index film layers are, for example, AlF₃, Al₂O₃, BaF₂, BiF₃, CaF₂, CeF₃, GdF₃, LiF, MgF₂, NaF, Na₃AlF₆, Na₅Al₃F₁₄, NdF₃, SiO₂, and Si₂O₃.

The materials of the anti-reflection layer 90 and the anti-reflection layer 92 can be the same or different. The materials of the anti-reflection layer 90 and the anti-reflection layer 92 can reflect the long-wavelength light to improve the efficiency of the elements, and can be, for example, a stacked film formed by stacking a plurality of high-reflective index film layers having a reflective index n greater than 1.9 and a plurality of low-reflective index film layers having a reflective index n less than 1.9. The high-reflective index film layers are, for example, CeO₂, Cr₂O₃, Gd₂O₃, HfO₂, In₂O₃, ITO, La₂O₃, Nb₂O₅, Nd₂O₃, PbO, SnO₂, Ta₂O₅, TiO₂, V₂O₅, WO₃, ZrO₂, ZnO, ZnS, and ZnSe. The low-reflective index film layers are, for example, AlF₃, Al₂O₃, BaF₂, BiF₃, CaF₂, CeF₃, GdF₃, LiF, MgF₂, NaF, Na₃AlF₆, Na₅Al₃F₁₄, NdF₃, SiO₂, and Si₂O₃.

Hereinafter, experimental results of the solar cell containing an anti-reflection layer and an optical filter of the present invention simulated by computer are illustrated.

The structure of the solar cell includes a first anti-reflection layer/a transparent substrate/a second anti-reflection layer/a front electrode/a photoelectric conversion layer/a back electrode in sequence. The first anti-reflection layer is composed of 104 nm MgF₂/23 nm TiO₂/17 nm MgF₂/96 nm TiO₂/13 nm MgF₂/29 nm TiO₂/38 nm MgF₂/11 nm TiO₂. The transparent substrate is glass. The second anti-reflection layer is made of 50 nm TiO₂. The front electrode is made of aluminium doped zinc oxide (AZO) having a thickness of 20 nm. The photoelectric conversion layer is made of amorphous silicon having a thickness of 300 nm. The back electrode is made of AZO having a thickness of 80 nm. The results show that the short circuit current density is J_{SC}=10.15 mA/cm², compared with the short circuit current density of J_{SC}=9.86 mA/cm² of the solar cell without the first anti-reflection layer and the second anti-reflection layer, the solar cell of the present invention having the anti-reflection layers can actually improve the short circuit current density.

The structure of the solar cell of another simulation experiment includes a first anti-reflection layer/a transparent substrate/a second anti-reflection layer/a front electrode/a photoelectric conversion layer/a back electrode/an optical filter in sequence. The first anti-reflection layer, the transparent substrate, the second anti-reflection layer, the front electrode, the photoelectric conversion layer, and the back electrode are the same as those of the previous simulation experiment. The optical filter is composed of 7 stacked layers of TiO₂ and SiO₂. The results show that the short circuit current density is J_{SC}=11.50 mA/cm², compared with the short circuit current density of J_{SC}=9.86 mA/cm² of the solar cell without the first anti-reflection layer, the second anti-reflection layer, and the photoelectric conversion layer, the solar cell of the present invention having the anti-reflection layers and the photoelectric conversion layer can significantly improve the short circuit current density.

The transparent solar cell module of the present invention has an optical filter added, thus being capable of alleviating the sunlight spectrum distortion problem, and adjusting the indoor color hue, the color rendering index, and the color temperature, thereby being capable of being used as BIPV, so as to achieve the purpose of being integrated with the building.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A transparent solar cell module, comprising:
a transparent solar cell, comprising:
a transparent substrate, comprising a first surface and a second surface;
a transparent solar cell part, located on the first surface of the transparent substrate; and
an optical filter, located on the transparent solar cell.

2. The transparent solar cell module according to claim 1, wherein the optical filter is located on the second surface of the transparent substrate.

3. The transparent solar cell module according to claim 1, further comprising at least one anti-reflection layer, located between the optical filter and the transparent substrate, or between the transparent substrate and the transparent solar cell part, or between the optical filter and the transparent substrate and between the transparent substrate and the transparent solar cell part.

4. The transparent solar cell module according to claim 1, wherein the optical filter is located between the first surface of the transparent substrate and the transparent solar cell part.

5. The transparent solar cell module according to claim 4, further comprising at least one anti-reflection layer, located on the second surface of the transparent substrate, or between the transparent substrate and the optical filter, or between the optical filter and the transparent solar cell part, or between the transparent substrate and the optical filter or between the optical filter and the transparent solar cell part alternatively and on the second surface of the transparent substrate.

6. The transparent solar cell module according to claim 1, wherein the transparent solar cell part is located between the optical filter and the transparent substrate.

7. The transparent solar cell module according to claim 1, further comprising at least one anti-reflection layer, located on the second surface of the transparent substrate, or between the transparent substrate and the transparent solar cell part, or on the second surface of the transparent substrate and between the transparent substrate and the transparent solar cell part.

8. The transparent solar cell module according to claim 1, further comprising another transparent substrate, wherein the transparent solar cell part is located between the transparent substrate and the another transparent substrate.

9. The transparent solar cell module according to claim 1, further comprising an insulation layer, located between the transparent solar cell part and the another transparent substrate.

10. The transparent solar cell module according to claim 1, wherein the optical filter limits a chromaticity diagram of Commission International de l'Eclairage (CIE) of the transparent solar cell within a rectangular region formed by CIE(0.10, 0.75) and CIE(0.25, 0.60).

11. The transparent solar cell module according to claim 1, wherein the optical filteradjusts a color rendering index (Ra) of the transmission spectrum of the transparent solar cell to be greater than 75.

12. The transparent solar cell module according to claim 1, wherein the optical filteradjusts a color temperature (CT) of the transmission spectrum of the transparent solar cell to 1000-10000 Kelvin degrees.

13. The transparent solar cell module according to claim 1, wherein the optical filter is a stacked film formed by stacking a plurality of high-reflective index film layers having a reflective index n greater than 1.9 and a plurality of low-reflective index film layers having a reflective index n less than 1.9.

14. The transparent solar cell module according to claim 1, wherein the first transparent substrate is a rigid substrate or a flexible substrate.

15. The transparent solar cell module according to claim 14, wherein the rigid substrate comprises a glass substrate.

16. The transparent solar cell module according to claim 14, wherein the flexible substrate comprises a plastic substrate.

17. The transparent solar cell module according to claim 1, wherein the transparent solar cell part comprises a first electrode, a second electrode, and a photoelectric conversion layer.

18. The transparent solar cell module according to claim 1, wherein the transparent solar cell part is a transparent silicon thin-film solar cell, a transparent dye-sensitized (DSSC) solar cell, a copper indium gallium diselenide (CIGS) solar cell part, a copper indium diselenide (CIS) solar cell part, a cadmium telluride (CdTe) solar cell part, or an transparent organic solar cell.
